(19) United States
(12) Patent Application Publication
(10) Pub. No.: US 2012/0043870 A1
(43) Pub. Date: Feb. 23, 2012

(54) DISTRIBUTION CABINET

(75) Inventors: Oliver Birkenstock, Berlin (DE); Adrian Benedetto, Berlin (DE); Philipp Meyer, Berlin (DE)

(73) Assignee: ADC GmbH, Berlin (DE)

(21) Appl. No.: 13/211,446

(22) Filed: Aug. 17, 2011

(30) Foreign Application Priority Data
Aug. 17, 2010 (DE) 10 2010 034 620.9

(51) Int. Cl. H05K 5/02; A47B 91/00

(52) U.S. Cl. 312/223.2; 312/351.1

(57) ABSTRACT

The invention relates to a distribution cabinet for communications and data technology, in which the distribution cabinet has lower horizontal lateral struts (1) of a rack and at least one baseplate (10), wherein the baseplate (10) is connected to at least one lower horizontal lateral strut (1), wherein the baseplate (10) has at least one circumferential seal (19) which is arranged on the lower face (12), and at least one latching lug (18) which projects beyond the outer rim, wherein the lower lateral struts (1) have at least one rest (6) which is directed into the distribution cabinet and has a sealing edge (7), wherein at least the lateral strut (1) which is adjacent to the latching lug (18) has a latching receptacle which the latching lug (18) enters, wherein the latching lug (18) exerts a force on the lateral strut (1) such that the sealing edge (7) is pressed against the circumferential seal (19) of the baseplate (10), and to a baseplate for a distribution cabinet for communications and data technology.

This application claims benefit of Serial No. 10 2010 034 620.9, filed 17 Aug. 2010 in Germany and which application is incorporated herein by reference. To the extent appropriate, a claim of priority is made to the above disclosed application.

### BACKGROUND

The invention relates to a distribution cabinet for communications and data technology, and to a baseplate for a distribution cabinet.

By way of example, one such distribution cabinet is known from DE 10 2008 056 062 B3. The distribution cabinet has a rack on which at least one roof module, side walls, at least one rear wall and at least one door are arranged. The rack has vertical struts and lower and upper horizontal struts, with the roof module being attached to the upper horizontal struts. A baseplate is attached to the lower lateral struts, through which baseplate cables can be passed, via seals, out of the bottom into the distribution cabinet. The baseplate is normally attached to the lateral struts by screw connections.

### SUMMARY

The invention is based on the technical problem of simplifying the assembly of a distribution cabinet, and of providing a baseplate which is suitable for this purpose.

For this purpose, the distribution cabinet for communications and data technology has lower horizontal lateral struts of a rack and at least one baseplate, wherein the baseplate is connected to at least one lower horizontal lateral strut, wherein the baseplate has at least one circumferential seal which is arranged on the lower face, and at least one latching lug which projects beyond the outer rim (or the faces), wherein the lower lateral struts have at least one rest which is directed into the distribution cabinet and has a sealing edge, wherein at least the lateral strut which is adjacent to the latching lug has a latching receptacle which the latching lug enters, wherein the latching lug exerts a force on the lateral strut such that the sealing edge is pressed against the circumferential seal of the baseplate. This enables the mounting of the baseplate without the use of tools, wherein the sealing requirements with reference to moisture can be adhered to.

The at least one seal on the lower face of the baseplate may in this case, for example, be connected to the baseplate by foam connection or adhesive bonding. It should also be noted that the seal need not completely cover the rest.

In one embodiment, the baseplate has at least one latching lug on each of at least two opposite faces. The seal is thus pressed on symmetrically. Furthermore, it is possible to provide a plurality of latching lugs on each face, and/or to provide at least one latching lug on each face such that the connection is made via all the lower lateral struts.

In a further embodiment, the baseplate has an upward bend, from which the latching lug is cut free, on the same face as the latching lug. In this case, the upward bend makes the baseplate more robust. In this case, it is also possible to provide upward bends without latching lugs on some or all of the faces, as well.

In a further embodiment, the latching receptacle is in the form of a continuous groove. This makes it easier to manufacture the lateral struts, for example as an extruded profile.

In a further embodiment, the sealing edge is cylindrical or at least partially cylindrical. The radial form results in a small contact-pressure edge, wherein the seal is not cut into by the rounded area.

### BRIEF DESCRIPTION OF THE DRAWINGS

The invention will be explained in more detail in the following text with reference to one preferred exemplary embodiment.

FIG. 1 shows a front view of a lower horizontal lateral strut,

FIG. 2 shows a perspective side view of the lateral strut,

FIG. 3 shows a perspective plan view of the upper face of a baseplate, and

FIG. 4 shows a plan view of the lower face of the baseplate.

### DETAILED DESCRIPTION

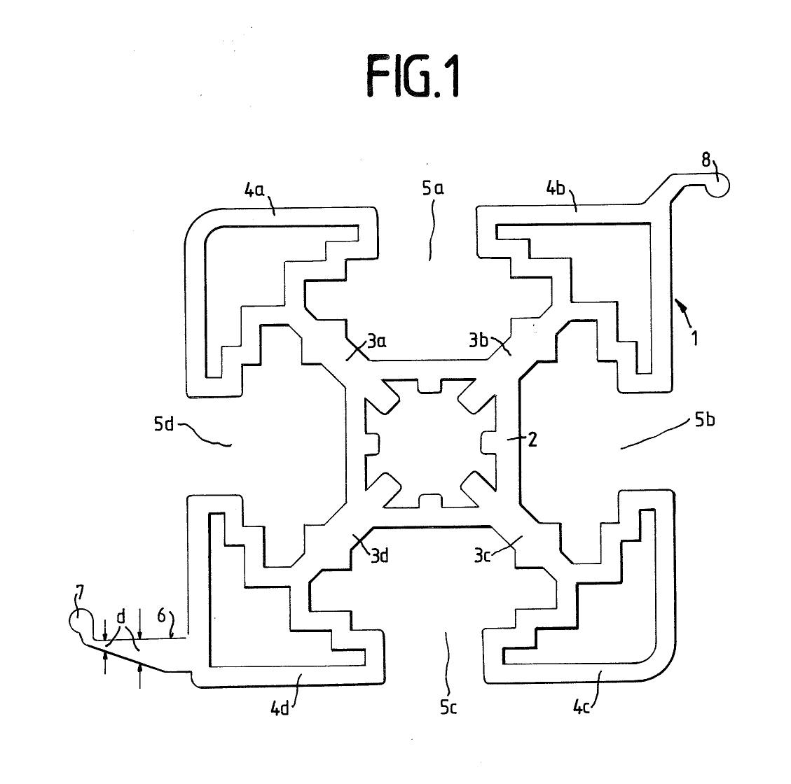

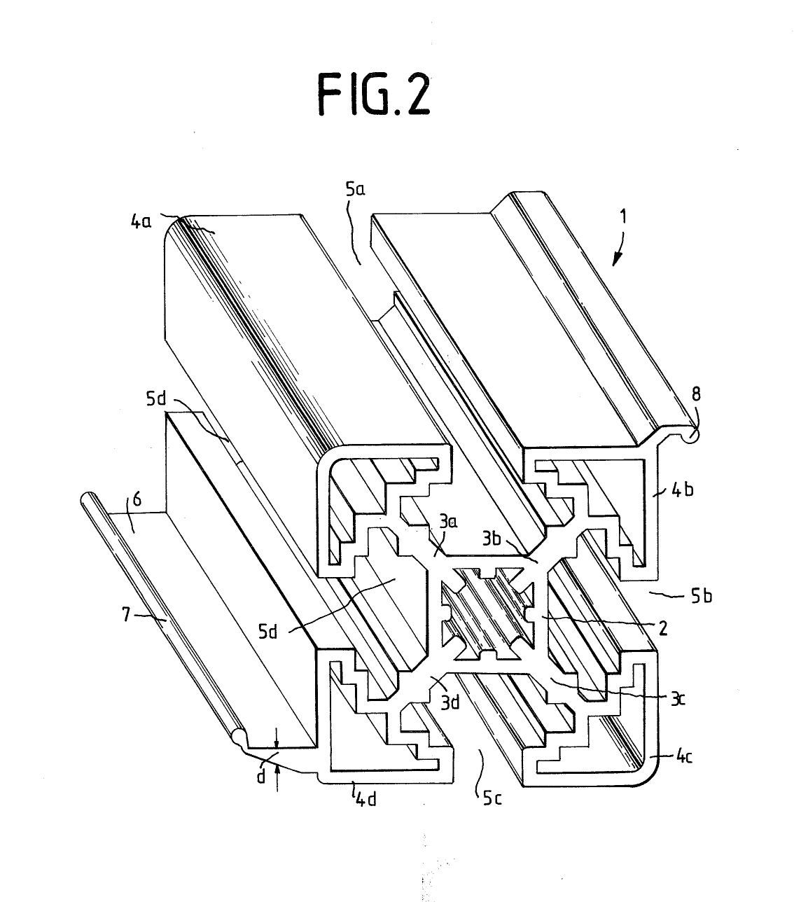

FIGS. 1 and 2 show a lower horizontal lateral strut 1. The lateral strut 1 has a center part 2 from which four limbs 3a-d project, each at an angle of 45°, and on each of which four corner pieces 4a-d are arranged. The lateral strut 1 is in this case designed to be light in weight and very robust. In this case, a groove 5a-d is respectively formed between each of two corner pieces 4a-d. A rest 6 is arranged on the left-hand lower corner piece 4d, and a cylindrical sealing edge 7 is arranged on the end of the rest 6. Starting from the corner piece 4d, the lower part of the rest 6 tapers such that the rest 6 has a smaller thickness d in the area of the sealing edge 7. This allows a certain springing effect in the area of the sealing edge 7. A stop edge 8 is arranged on the upper right-hand corner piece 4b. A rear wall, a side wall or a door can then be arranged in a defined manner on this stop edge 8, defined on the basis of the installation location of the lateral strut 1.

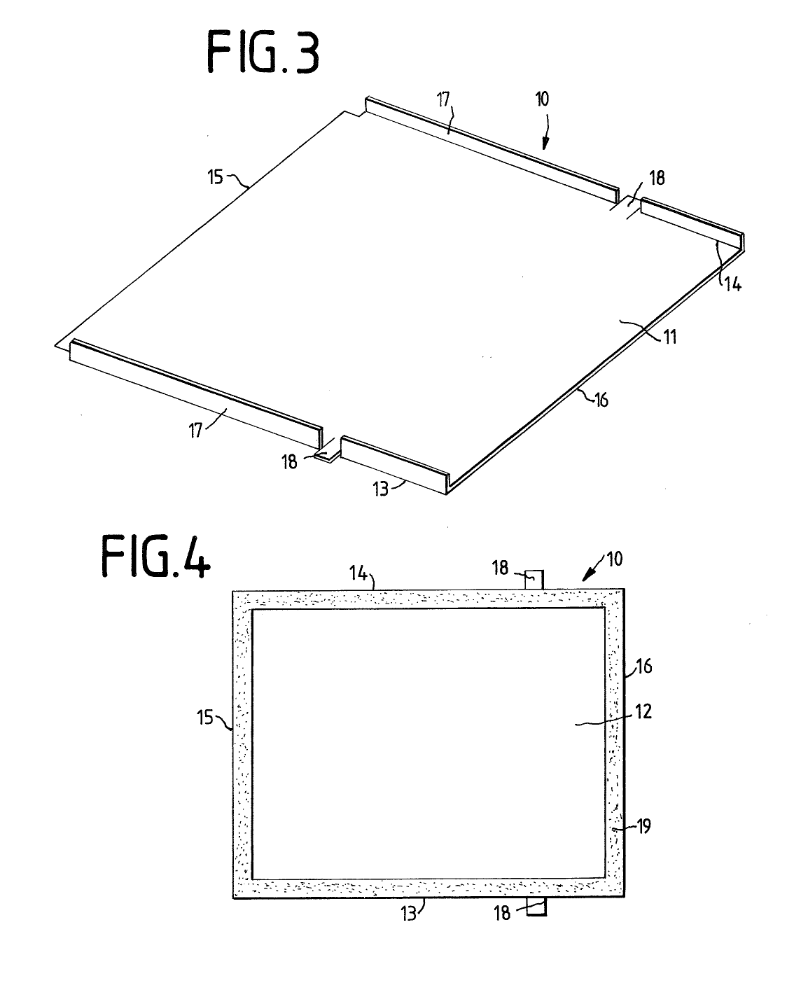

FIGS. 3 and 4 show a baseplate 10. The baseplate 10 has an upper face 11, a lower face 12, a front face 13, a rear face 14, a left-hand face 15 and a right-hand face 16. An upward bend 17 is in each case arranged on the front face 13 and on the rear face 14, and a latching lug 18 is cut free from each upward bend 17. A circumferential seal 19 is arranged on the lower face 12 and is connected, for example, by foam to the baseplate 10.

For assembly, the baseplate 10 is moved from above, with the lower face 12 pointing downward, in the direction of the lower horizontal lateral struts 1. In the process, the latching lugs 18 are moved by the upper inner corner pieces 4a in the direction of the upward bend 17 in order to finally enter the groove 5d, which is formed between the upper inner corner piece 4a and the corner piece 4d with the rest 6. At the same time, the seal 19 lies on the rest 6 and on the sealing edge 7. In the process, the sealing edge 7 presses into the seal 19 and seals the internal area of the distribution cabinet. In the process, the latching lug 18 presses from the inside against the inner upper corner piece 4a, and thus exerts a force on the lateral strut 1 upward, which leads to the sealing edge 7 being pressed further against the seal 18.

### LIST OF REFERENCE SYMBOLS

1 Lateral strut
2 Center part
3a-d Limb
4a-d Corner piece
5a-d Groove
6 Rest
7 Sealing edge
8 Stop edge
10 Baseplate
11 Upper face
12 Lower face
13 Front face
14 Rear face
15 Left-hand face
16 Right-hand face
17 Upward bend
18 Latching lug
19 Seal

1. A distribution cabinet for communications and data technology, the distribution cabinet comprising: a rack including at lease one lower horizontal lateral strut and at least one baseplate, wherein the baseplate is connected to the lower horizontal lateral strut, wherein the baseplate has a circumferential seal which is arranged on a lower face, and at least one latching lug which projects beyond an outer rim, wherein the lower horizontal lateral strut has a rest which is directed into the distribution cabinet and has a sealing edge, wherein the lower horizontal lateral strut which is adjacent to the latching lug has a latching receptacle which the latching lug enters, wherein the latching lug exerts a force on the lower horizontal lateral strut such that the sealing edge is pressed against the circumferential seal of the baseplate.

2. The distribution cabinet as claimed in claim 1, wherein the baseplate has at least one latching lug on each of at least two opposite faces.

3. The distribution cabinet as claimed in claim 1, wherein the baseplate has an upward bend, from which the latching lug is cut free, on the same face as the latching lug.

4. The distribution cabinet as claimed in claim 1, wherein the latching receptacle is in the form of a continuous groove.

5. The distribution cabinet as claimed in claim 1, wherein the sealing edge is cylindrical.

6. A baseplate for a distribution cabinet for communications and data technology, comprising: a baseplate body, wherein the baseplate body has at least one circumferential seal which is arranged on a lower face, and at least one latching lug which projects beyond an outer rim.
